(19) United States
(12) Patent Application Publication
(10) Pub. No.: US 2008/0157366 A1
(43) Pub. Date: Jul. 3, 2008

(54) SEMICONDUCTOR DEVICE AND FABRICATING METHOD THEREOF

(76) Inventor: Ji-Won Hyun, Daegu (KR)

Correspondence Address: SHERR & NOURSE, PLLC, 620 HERNDON PARKWAY, SUITE 200, HERNDON, VA, 20170, US

(21) Appl. No.: 11/954,197

(22) Filed: Dec. 11, 2007

(30) Foreign Application Priority Data
Dec. 29, 2006 (KR) 10-2006-0137279

(51) Int. Cl. H01L 23/48; H01L 21/44

(52) U.S. Cl. 257/750; 438/598; 257/E23.167; 257/E21.575

(57) ABSTRACT

A semiconductor device and fabricating method thereof are disclosed. Embodiments relate to forming metal lines having a prescribed pattern over a lower insulating interlayer, forming a silicon oxide layer over surfaces of the metal lines and a surface of the lower insulating interlayer exposed between the metal lines, and forming an upper insulating interlayer over the silicon oxide layer.

The present application claims priority under 35 U.S.C. 119 to Korean Patent Application No. 10-2006-0137279, filed on Dec. 29, 2006, which is hereby incorporated by reference in its entirety.

### BACKGROUND

In a semiconductor fabricating process, a metal line may be formed by depositing a metal layer. The layer may be coated with photoresist, which is developed to form a photoresist pattern. A metal pattern is formed by etching the metal layer. An oxide layer of SiO₂ may then be deposited by HDP (high density plasma). In the metal layer depositing step, there may be particles on the metal, and it may be difficult to etch a specific pattern. An abnormal metal line may be formed with a protrusion defect.

FIG. 1A and FIG. 1B show problems in a semiconductor device fabricating method according to the related art. FIG. 1A is a SEM picture of a metal line layout and FIG. 1B is a cross-sectional diagram. Referring to FIG. 1A and FIG. 1B, when metal lines 12 are formed on a lower insulating interlayer 11, if a stray particle lies in a gap between the metal lines 12, the subsequent etch may not be successfully performed, and a protrusion defect 13 may occur. Subsequently, in depositing an upper insulating interlayer 14 which fills the gap between the metal lines 12, the area with the protrusion defect 13 may not be correctly filled up with the oxide insulator. This may result in the formation of a void 15. As semiconductor devices become more highly integrated, the metal lines 12 become more ultra-microscopic. If a protrusion defect 13 is generated, the gap between the metal lines 12 gets narrower. Thus, it is difficult to achieve a complete filling of the gap between metal lines. When thermal stresses are applied to the defect region by an EM (electro-migration) test and/or an EFR (early failure rate) test, the void causes the metal lines to fail. An inter-metal bridge may be generated, which degrades reliability of device.

### SUMMARY

Embodiments relate to semiconductor device fabrication, and more particularly, to a semiconductor device and fabricating method thereof. Embodiments relate to preventing a bridge effect between metal lines by having a gap between ultra-microscopic metal lines filled up with an insulating interlayer.

Embodiments relate to a semiconductor device and fabricating method thereof, by which a gap between metal lines of the semiconductor device can be completely filled up with an insulating interlayer. Embodiments relate to semiconductor devices and fabricating methods in which inter-metal-line bridges can be prevented when thermal stresses are applied to the semiconductor devices. Embodiments relate to semiconductor devices and fabrication methods by which fault resistance to any applied thermal stresses, including EM and/or EFR tests, are improved to enhance reliability.

Embodiments relate to a method of fabricating a semiconductor device by forming metal lines having a prescribed pattern over a lower insulating interlayer. A silicon oxide layer may be formed over surfaces of the metal lines and a surface of the lower insulating interlayer exposed between the metal lines. An upper insulating interlayer may be formed over the silicon oxide layer. The relatively thin silicon oxide layer may be formed on the surface of the insulating interlayer using ozone-tetraethoxysilane (O₃-TEOS). The silicon oxide layer may be formed by atomic layer deposition.

The silicon oxide layer forming step may include the steps of introducing TEOS using inert gas as a carrier, performing pumping until a base pressure is reached, and introducing O₃.

The TEOS introducing step may be performed while a pressure below 10 Torr is maintained at 300˜400° C. And, the silicon oxide layer forming step may be repeated until a thickness of an O₃-TEOS insulating layer as the silicon oxide layer reaches 300˜500 Å.

The upper insulating interlayer may include a USG layer and a d-TEOS layer.

The upper insulating interlayer may be formed by high density plasma deposition.

Embodiments relate to a semiconductor device includes metal lines having a prescribed pattern over a lower insulating interlayer, a silicon oxide layer over surfaces of the metal lines and a surface of the lower insulating interlayer exposed between the metal lines, and an upper insulating interlayer over the silicon oxide layer.

The silicon oxide layer may include an O₃-TEOS insulating layer.

### DRAWINGS

FIG. 1A and FIG. 1B are diagrams to explain a problem of a semiconductor device fabricating method according to a related art.

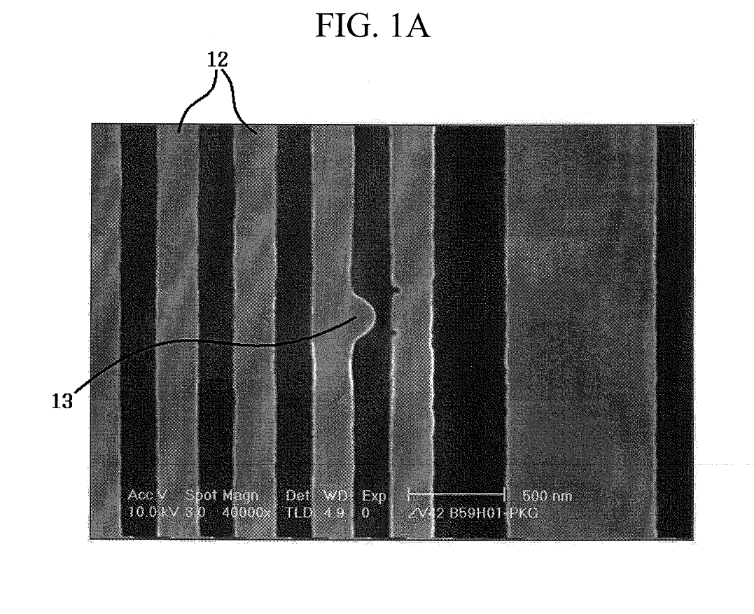

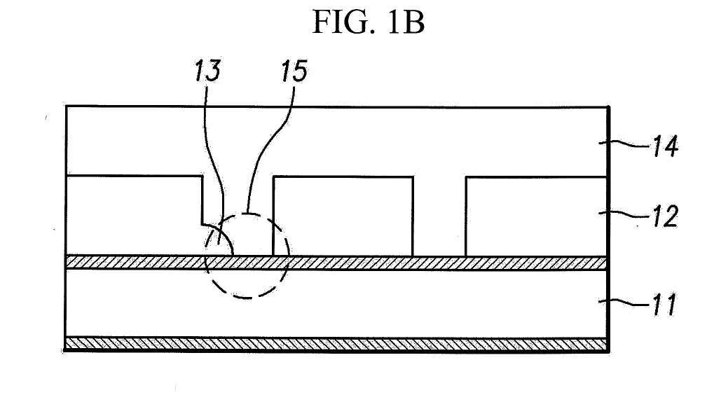

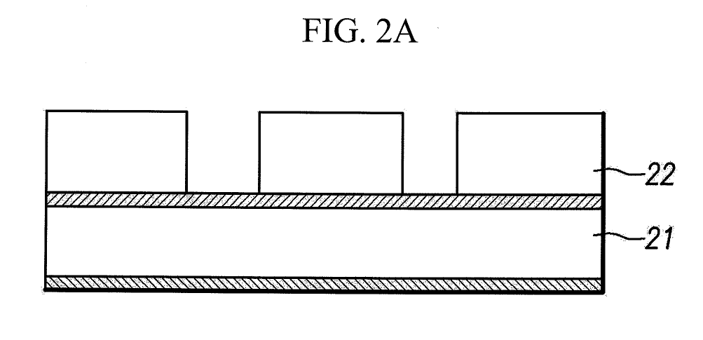

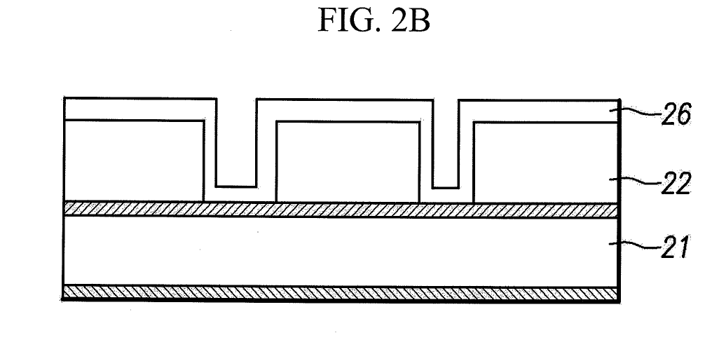

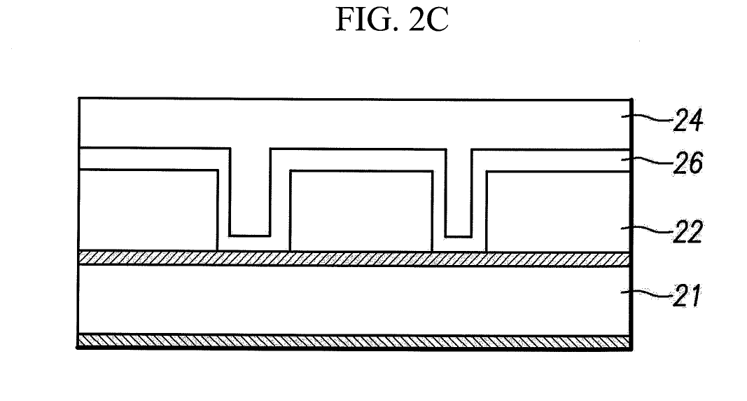

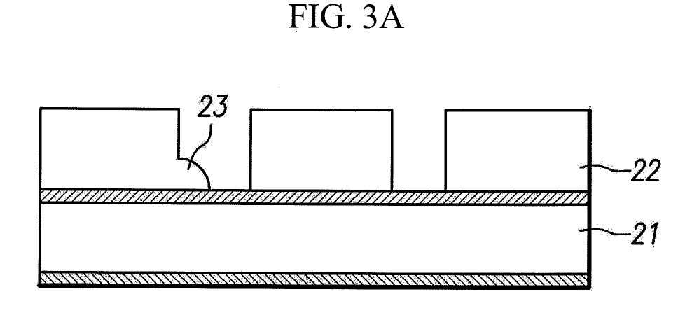

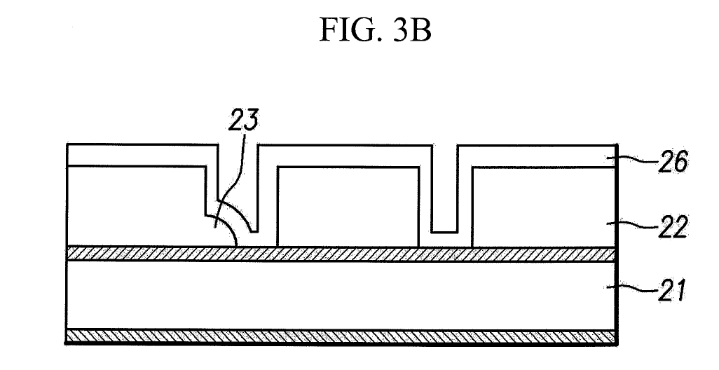

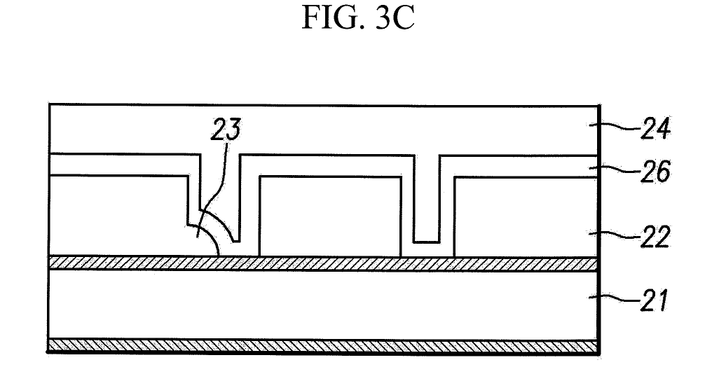

Example FIGS. 2A to 2C are cross-sectional diagrams of a semiconductor device and fabricating method thereof according to embodiments.

Example FIGS. 3A to 3C are cross-sectional diagrams of a semiconductor device and fabricating method thereof according to embodiments.

### DESCRIPTION

Example FIGS. 2A to 2C are cross-sectional diagrams of a semiconductor device and fabricating method thereof according to embodiments. Referring to example FIG. 2A, metal lines 22 having a prescribed pattern are formed over a lower insulating interlayer 21. The metal lines 22 may be formed by a metal line forming process technique such as reactive ion etch (RIE).

Referring to example FIG. 2B, a relatively thin O₃-TEOS insulating layer 26 is formed over surfaces of the metal lines 22 and surfaces of the lower insulating interlayer 21 exposed between the metal lines 22. The O₃-TEOS insulating layer 26 may be formed by ALD (atomic layer deposition). Details of an example of the formation of the O₃-TEOS insulating layer 26 are explained below.

TEOS (tetra ethyl orthosilicate) may be introduced into a chamber using inert gas such as He as a carrier. The pressure may be maintained below approximately 10 Torr and the temperature may be maintained at approximately 300˜400° C. After the TEOS introduction, pumping is carried out until a base pressure is reached. O₃ is then introduced into the chamber. Oxygen (O) dissociated from O₃ causes decomposition of the adsorbed TEOS to reconfigure Si—O—Si or Si—O—H. Thus, the O₃-TEOS insulating layer 26 of silicon oxide grows. The growth thickness of the O₃-TEOS insulating layer 26 corresponds to several angstroms (Å). After the introduction of O₃ has been stopped, pumping is carried out to reach the base pressure again. The above steps may be repeated from the TEOS introducing step until the thickness of the O₃-TEOS insulating layer 26 reaches approximately 300˜500 Å.

The method of forming the O₃-TEOS insulating layer 26 explained above grows a silicon oxide layer by the repetition of TEOS surface adsorption and dissolution. Hence, the microscopic gap between the metal lines 22 may be completely filled up with the silicon oxide layer. Since probability of adsorption is equal across the whole surface, complete filling of gaps between the metal lines can be expected.

Referring to example FIG. 2C, an upper insulating interlayer 24 is deposited over the O₃-TEOS insulating layer 26. The upper insulating interlayer 24 includes a USG (undoped silicate glass) layer of about 3000 Å and a d-TEOS layer of about 6,000 Å. The deposition of the upper insulating interlayer 24 may be carried out using a high-density plasma process.

Thus, if the upper insulating interlayer 24 is deposited after completion of the O₃-TEOS insulating layer 26, the gap between the ultra-microscopic metal lines 22 having a protrusion defect therein can be completely filled up with the upper insulating interlayer 24. This is explained in the following description.

Example FIGS. 3A to 3C are cross-sectional diagrams of a semiconductor device and fabricating method thereof according to embodiments. If a protrusion defect 23, as shown in example FIG. 3A, occurs in a gap between metal lines 22, a relatively thin O₃-TEOS insulating layer 26, as shown in example FIG. 3B, may be formed by atomic layer deposition. Subsequently, an upper insulating interlayer 24, as shown in example FIG. 3C, may be deposited over the O₃-TEOS insulating layer 24. Therefore, the gap between the ultra-microscopic metal lines 22 having a protrusion defect 23 can be completely filled up with the insulating interlayer 24.

After metal lines have been formed, a relatively thin O₃-TEOS insulating layer may be formed by atomic layer deposition before forming an insulating interlayer. Hence, a gap between the ultra-microscopic metal lines can be completely filled up with the insulating interlayer.

Even if a thermal stress is applied to a semiconductor device, the embodiments prevent an inter-metal-line bridge effect. Hence, the embodiments improve EM and EFR characteristics, thereby enhancing device reliability.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming metal lines having a prescribed pattern over a lower insulating interlayer;
forming a silicon oxide layer over surfaces of the metal lines and surfaces of the lower insulating interlayer exposed between the metal lines; and
forming an upper insulating interlayer over the silicon oxide layer.

2. The method of claim 1, wherein the silicon oxide is a relatively thin layer formed over the surface of the insulating interlayer.

3. The method of claim 1, wherein the silicon oxide layer is formed using O₃-TEOS.

4. The method of claim 1, wherein the silicon oxide layer is formed by atomic layer deposition.

5. The method of claim 1, wherein forming the silicon oxide layer comprises:
introducing TEOS using inert gas as a carrier;
pumping until a base pressure is reached; and
introducing O₃.

6. The method of claim 5, wherein the TEOS is introduced at a pressure maintained below approximately 10 Torr.

7. The method of claim 6, wherein the TEOS is at a temperature of approximately 300° C. to 400° C.

8. The method of claim 5, wherein forming the silicon oxide layer is repeated until a thickness of an O₃-TEOS insulating layer reaches approximately 300 Å to 500 Å.

9. The method of claim 1, wherein the upper insulating interlayer comprises a undoped silicate glass layer.

10. The method of claim 1, wherein the upper insulating interlayer comprises a d-TEOS layer.

11. The method of claim 1, wherein the upper insulating interlayer is formed by high density plasma deposition.

12. A semiconductor device, comprising:
metal lines having a prescribed pattern over a lower insulating interlayer;
a silicon oxide layer formed over surfaces of the metal lines and a surface of the lower insulating interlayer exposed between the metal lines; and
an upper insulating interlayer formed over the silicon oxide layer.

13. The semiconductor device of claim 9, wherein the silicon oxide layer comprises an O₃-TEOS insulating layer.

14. An apparatus comprising:
metal lines formed having a prescribed pattern over a lower insulating interlayer;
a silicon oxide layer formed over surfaces of the metal lines and surfaces of the lower insulating interlayer exposed between the metal lines; and
an upper insulating interlayer formed over the silicon oxide layer.

15. The apparatus of claim 14, wherein the silicon oxide is a relatively thin layer of O₃-TEOS formed over the surface of the insulating interlayer.

16. The apparatus of claim 14, wherein the silicon oxide layer is formed by atomic layer deposition.

17. The apparatus of claim 14, wherein the silicon oxide layer is formed by:
introducing TEOS using inert gas as a carrier;
pumping until a base pressure is reached; and
introducing O₃.

18. The apparatus of claim 17, wherein TEOS is introduced at a pressure maintained below approximately 10 Torr and at a temperature of approximately 300° C. to 400° C.

19. The apparatus of claim 17, wherein the silicon oxide layer is formed from O₃-TEOS to have a thickness of approximately 300 Å to 500 Å.

20. The apparatus of claim 14, wherein the upper insulating interlayer comprises an undoped silicate glass layer.
